(19) United States
(12) Patent Application Publication
(10) Pub. No.: US 2026/0321557 A1
(43) Pub. Date: Oct. 15, 2026

(54) SELF-CLEANING INDUCTIVELY COUPLED PLASMA SOURCE

(71) Applicant: LAM RESEARCH CORPORATION, Fremont, CA (US)

(72) Inventors: Karl Frederick LEESER, West Linn, OR (US); Kaihan ASHTIANI, Cupertino, CA (US)

(21) Appl. No.: 19/483,820

(22) PCT Filed: May 7, 2024
(86) PCT No.: PCT/US2024/028107

§ 371 Date: Nov. 12, 2025

Related U.S. Application Data
(60) Provisional application No. 63/467,761, filed on May 19, 2023.

(51) Int. Cl. H01J 37/32; C23C 16/44; C23C 16/455; C23C 16/458; C23C 16/505; H10P 14/43

(52) U.S. Cl. CPC H01J 37/32862; C23C 16/4407; C23C 16/45536; C23C 16/45544; C23C 16/4583; C23C 16/505; H01J 37/3211; H01J 37/32422; H01J 37/3244; H01J 2237/332; H10P 14/43

(57) ABSTRACT

A substrate processing system includes a processing chamber, a plasma source, a first coil and a second coil, and a power supply. The plasma source is configured to supply a plasma to the processing chamber through a gas distribution device disposed between the processing chamber and the plasma source. The first coil and the second coil disposed interstitially on the plasma source and configured to ignite a gas supplied to the plasma source to generate the plasma. The power supply is configured to supply power to the first coil and the second coil in an alternating manner

### CROSS-REFERENCE TO RELATED APPLICATIONS

This application claims the benefit of U.S. Provisional Application No. 63/467,761, filed on May 19, 2023. The entire disclosure of the application referenced above is incorporated herein by reference.

### FIELD

The present disclosure relates generally to substrate processing systems and more particularly to self-cleaning inductively coupled plasma source.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Atomic Layer Deposition (ALD) is a thin-film deposition method that sequentially performs a gaseous chemical process to deposit a thin film on a surface of a material (e.g., a surface of a substrate such as a semiconductor wafer). Most ALD processes use at least two chemicals called precursors (reactants) that react with the surface of the material one precursor at a time in a sequential, self-limiting manner. For example, a typical ALD process includes a series of dose and purge steps that are performed sequentially and repeatedly. Through repeated exposure to separate precursors, a thin film is gradually deposited on the surface of the material.

A plasma enhanced ALD (PEALD) process uses plasma following the dose steps. In some substrate processing systems, the plasma may be generated in-situ in a processing chamber. Alternatively, the plasma may be generated externally or remotely from the processing chamber and supplied to the processing chamber.

### SUMMARY

A substrate processing system comprises a processing chamber, a plasma source, a first coil and a second coil, and a power supply. The plasma source is configured to supply a plasma to the processing chamber through a gas distribution device disposed between the processing chamber and the plasma source. The first coil and the second are coil disposed interstitially on the plasma source and are configured to ignite a gas supplied to the plasma source to generate the plasma. The power supply is configured to supply power to the first coil and the second coil in an alternating manner.

In additional features, the power supply is configured to supply more power to the first coil than to the second coil.

In additional features, windings of the first coil and the second coil are interlaced with each other.

In additional features, the first coil and the second coil are electrically isolated from each other.

In additional features, the substrate processing system further comprises a switching circuit connected to the power supply. The switching circuit comprises a first output connected to the first coil and a second output connected to the second coil. The switching circuit is configured to supply the power from the power supply to the first and second coils via the first and second outputs, respectively, in the alternating manner.

In additional features, the power supply is configured to supply a first radio frequency power to the first coil and supply a second radio frequency power to the second coil.

In additional features, the first radio frequency power supplied to the first coil is greater than the second radio frequency power supplied to the second coil.

In additional features, the power supply is configured to supply the first radio frequency power to the first coil for a first time period and to supply the second radio frequency power to the second coil for a second time period.

In additional features, the first time period is greater than the second time period.

In additional features, the first radio frequency power supplied to the first coil for the first time period is greater than the second radio frequency power supplied to the second coil for the second time period. The first time period is greater than the second time period.

In additional features, the power supply is configured to supply the power to the first coil to generate the plasma.

In additional features, the power supply is configured to supply the power to the second coil to erode material deposited on an inner surface of the plasma source in regions between windings of the first coil.

In additional features, the plasma source is dome shaped, cylindrical, elliptical, or conical.

In additional features, the plasma source is dome shaped, cylindrical, elliptical, or conical. The first and second coils are disposed around the plasma source.

In additional features, the plasma source is cylindrical with a first end coupled to the gas distribution device. The first and second coils are disposed on a surface at a second end of the plasma source.

In additional features, the substrate processing system further comprises an injector and a pedestal. The injector is coupled to the plasma source. The injector is configured to inject a gas into the plasma source to generate the plasma. The pedestal is arranged in the processing chamber to support a substrate. The gas distribution device is configured to filter ions from the plasma and to supply radicals from the plasma into the processing chamber to process the substrate.

In still other features, a substrate processing system comprises a processing chamber, a plasma source, a coil, and an actuator configured to shift a position of the coil on the plasma source. The plasma source is configured to supply a plasma to the processing chamber through a gas distribution device disposed between the processing chamber and the plasma source. The coil is disposed on the plasma source and is configured to ignite a gas supplied to the plasma source to generate the plasma; and

In additional features, the substrate processing system further comprises a power supply configured to supply power to the coil to ignite the gas. The actuator is configured to shift the position of the coil while the power supply supplies power to the coil.

In additional features, the actuator is configured to shift the position of the coil to erode material deposited on an inner surface of the plasma source in regions between windings of the coil.

In additional features, the actuator is configured to shift the position of the coil intermittently.

In additional features, the actuator is configured to shift the position of the coil periodically.

In additional features, the actuator is configured to shift the position of the coil repeatedly between two positions.

In additional features, the actuator is configured to shift the position of the coil linearly between two positions.

In additional features, the actuator is configured to shift the position of the coil by rotating the coil to move windings of the coil over different regions of the plasma source.

In additional features, the actuator is configured to shift the position of the coil by compressing and decompressing the coil.

In additional features, the actuator is configured to shift the position of the coil by dithering the coil.

In additional features, the plasma source is dome shaped, cylindrical, elliptical, or conical.

In additional features, the plasma source is dome shaped, cylindrical, elliptical, or conical. The coil is disposed around the plasma source.

In additional features, the plasma source is cylindrical with a first end coupled to the gas distribution device. The coil is disposed on a surface at a second end of the plasma source.

In additional features, the substrate processing system further comprises an injector and a pedestal. The injector is coupled to the plasma source. The injector is configured to inject a gas into the plasma source to generate the plasma. The pedestal is arranged in the processing chamber to support a substrate. The gas distribution device is configured to filter ions from the plasma and supply radicals from the plasma into the processing chamber to process the substrate.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system comprising an inductively coupled plasma (ICP) source;

FIG. 2 shows an example of a substrate processing system with dual radio frequency (RF) antennas and a dome shaped ICP plasma source;

FIGS. 3A and 3B show examples of substrate processing systems with dual RF antennas and a cylindrical ICP plasma source;

FIG. 4 shows an example of a substrate processing system with dual RF antennas and an elliptical ICP plasma source;

FIG. 5 shows an example of a substrate processing system with dual RF antennas and a conical ICP plasma source;

FIG. 6 shows an example of a substrate processing system with a single spatially movable RF antenna and a dome shaped ICP plasma source;

FIGS. 7A and 7B show examples of substrate processing systems with a single spatially movable RF antenna and a cylindrical ICP plasma source;

FIG. 8 shows an example of a substrate processing system with a single spatially movable RF antenna and an elliptical ICP plasma source;

FIG. 9 shows an example of a substrate processing system with a single spatially movable RF antenna and a conical ICP plasma source;

FIG. 10 shows a method of operating the substrate processing systems of FIGS. 2-5 with the dual RF antennas; and

FIG. 11 shows a method of operating the substrate processing systems of FIGS. 6-9 with the single spatially movable RF antenna.

In the drawings, reference numbers may be reused to identify similar and/or identical elements.

### DETAILED DESCRIPTION

Typically, inductively coupled plasma (ICP) plasma sources are not used to deposit conductive films on substrates such as semiconductor wafers. However, since the ICP plasma sources can generally achieve much higher plasma densities and associated higher radical fluxes that other types of plasma sources, the ICP plasma sources are attractive candidates for challenging applications such as depositing conductive films on substrates such as semiconductor wafers.

The ICP plasma sources typically employ a solid dielectric window to separate a helical, coil-shaped antenna, which is excited by radio frequency (RF) power, from the plasma generated in a processing chamber. If a conductive film is deposited on a substrate in the processing chamber using an ICP plasma source, the conductive film is also slowly deposited on the dielectric window in regions that are not under the antenna. The deposition of the conductive film on the dielectric window in the regions that are not under the antenna may be called “window clouding.”

The conductive film deposited on the dielectric window in the regions that are not under the antenna increasingly acts as a faraday cage to screen out electric fields from the antenna and interferes with consistent power coupling to the plasma. A primary negative effect of the screening out of the electric fields from the antenna and the interference with consistent power coupling to the plasma is process drift. Process drift can cause non-uniformities in substrate processing and is therefore highly undesirable in semiconductor fabrication processes.

Several solution are proposed to overcome the issue of inadvertent conductive film deposition within an ICP plasma source which would otherwise prevent inductive coupling through the dielectric window or dome. For example, one solution is to completely insert and immerse a coil (i.e., the antenna) into vacuum in the processing chamber with no dielectric window. However, in such a configuration, the coil itself sputters onto the substrate being processed in the processing chamber. The sputtering is unacceptable in some applications involving deposition of conductive films performed using ICP plasma sources.

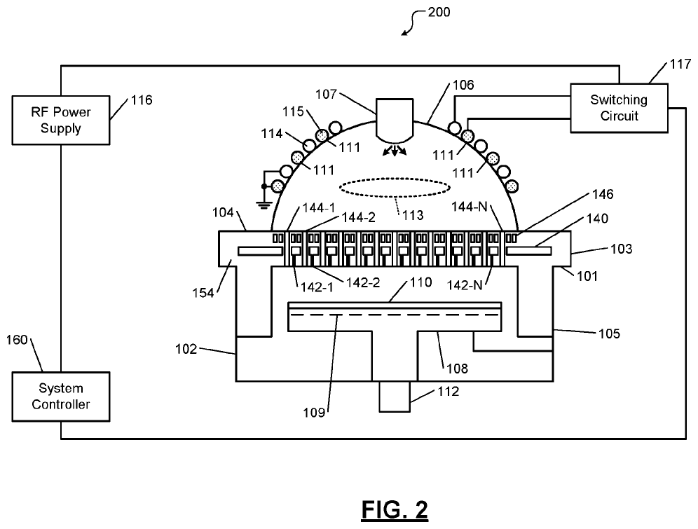

The present disclosure provides two methods to overcome the window clouding. In a first method, a secondary antenna is used. In a second method, a single antenna with spatial movement of the antenna is used. These methods are initially briefly described below and subsequently described below in detail with reference to FIG. 2 onwards.

Secondary antenna: Sometimes, no window clouding occurs directly under the antenna. This is likely due to localized continuous sputtering in the vicinity of the antenna. If a secondary coil is co-wound and spatially interlaced with the primary antenna, a scheme can be employed where periodically, the primary antenna can be energized and periodically, the alternate, secondary antenna can be energized. At any given time, the majority, if not all, of the RF power is applied to only one antenna.

Spatial movement of the antenna: In this scheme, a single antenna is used and is slowly moved such that the region of sputter is continuously moving to effectively clean different parts of the dielectric window. The coil can be moved in different ways depending on the shape of the plasma source (e.g., dome shape, cylindrical, elliptical, hemispherical, conical, and so on) and depending on how the coil is disposed around the plasma source. For example, the coil can be rotated around a vertical axis of the plasma source, oscillated (e.g., compressed and decompressed) around a vertical axis of the plasma source, rotated or linearly displaced back and forth on a top surface of the plasma source (e.g., a cylindrical plasma source), and so on.

The movement may be continuous or intermittent. The movement can position different portions of the coil at different locations around the plasma source at different times. The movement can not only minimize deposition of the conductive film on the dielectric window but can also clean any residual deposition of the conductive film that may occur on the dielectric window.

Examples of mechanisms used to move the antenna include a stepper motor. The antenna can be rotated by rotating the entire electrical system itself (e.g., by rotating the RF power supply and the coil). The antenna can also be rotated using an electrical rotation coupling device such as an electrical slip ring. Other examples of slip rings include liquid mercury slip rings, ball bearing based slip rings, and so on.

The dual antenna scheme and the antenna spatial movement scheme overcome a key limitation of the application of conventional ICP plasma sources to conductive film deposition by providing self-cleaning of the dielectric window. For example, in the secondary antenna scheme, when the primary antenna is energized and the secondary antenna is not energized, material can build up on the dielectric window under the secondary antenna. Subsequently, when the primary antenna is deenergized and the secondary antenna is energized, the buildup under the secondary antenna gets eroded. Similarly, when the secondary antenna is energized and the primary antenna is not energized, material can build up on the dielectric window under the primary antenna. Subsequently, when the secondary antenna is deenergized and the primary antenna is energized, the buildup under the primary antenna gets eroded. In the spatial movement scheme, any buildup that may occur between segments of the antenna gets eroded (cleaned) when the antenna is moved.

In the antenna spatial movement schemes, the movement of the antenna can not only minimize deposition of the conductive film on the dielectric window but can also clean any residual deposition of the conductive film that may occur on the dielectric window during substrate processing. These and other features of the present disclosure are described below in detail.

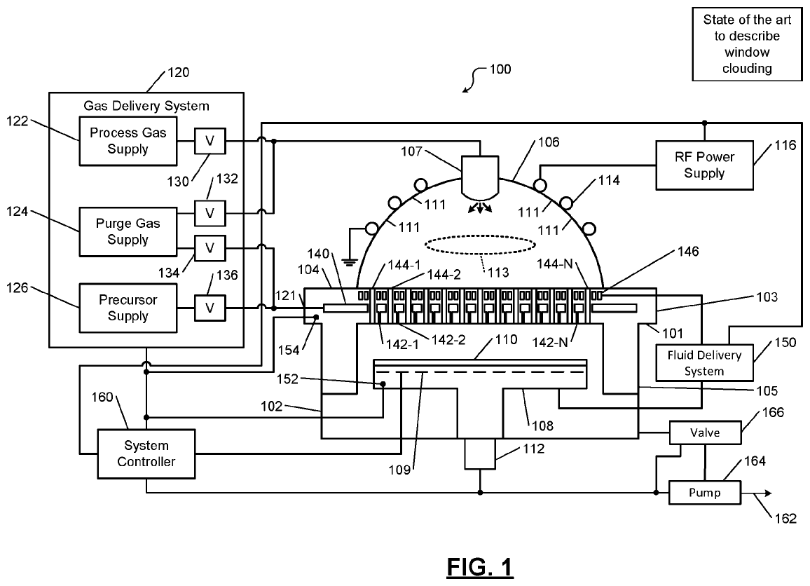

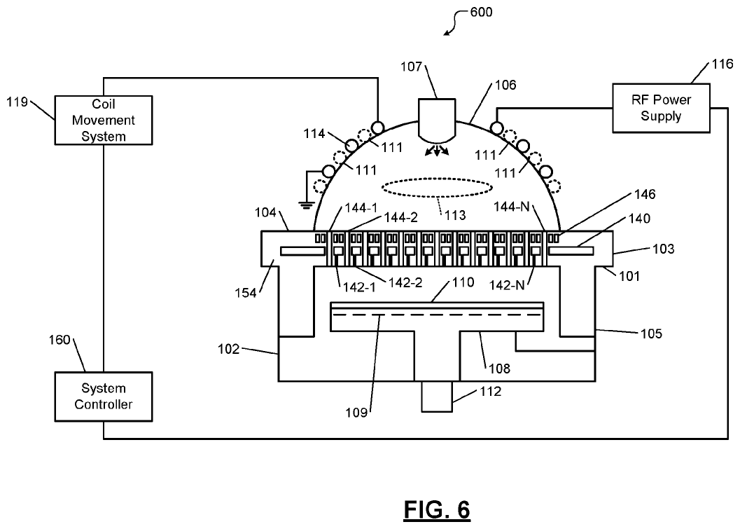

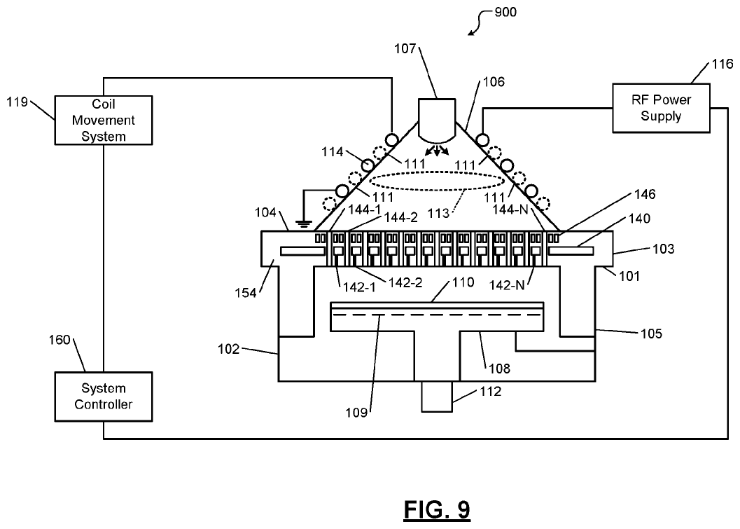

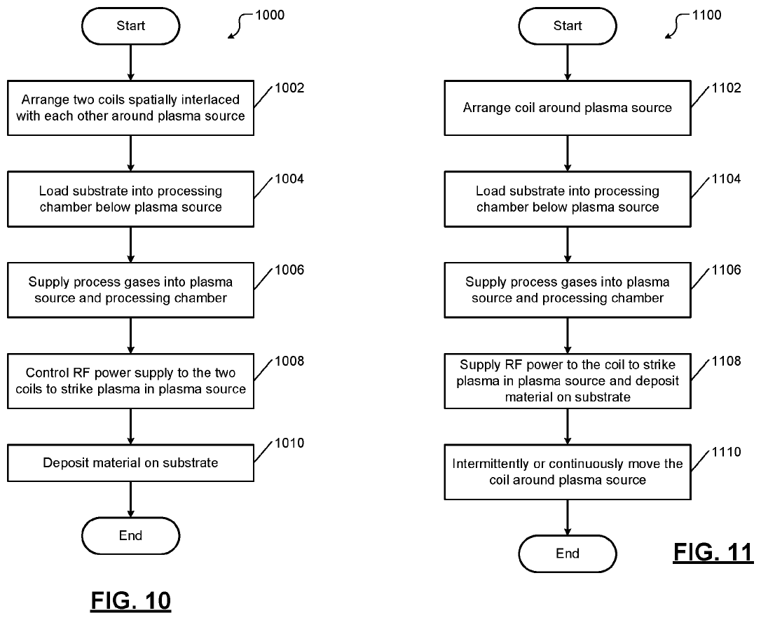

The present disclosure is organized as follows. In a first section, an example of a substrate processing system comprising an ICP plasma source is shown and described with reference to FIG. 1. In sections 2-5, examples of substrate processing systems comprising dual antennas and ICP plasma sources of different geometries are shown and described with reference to FIGS. 2-5. In sections 6-9, examples of substrate processing systems comprising a spatially movable antenna and ICP plasma sources of different geometries are shown and described with reference to FIGS. 6-9. In sections 10 and 11, methods of operating the substrate processing systems with the dual antennas and the spatially movable single antenna are shown and described with reference to FIGS. 9 and 10.

### Section 1: Example of Substrate Processing System

FIG. 1 shows an example of a substrate processing system 100 comprising a processing chamber 102, a dual plenum showerhead 104, and a dome shaped plasma source 106. The dome shape is shown for example only. The plasma source 106 can be of any other shape (e.g., elliptical, cylindrical, etc.) as shown in subsequent figures. In the example shown, the plasma source 106 has a circular base portion. The plasma source 106 extends upwards from the circular base portion with a dome shaped (e.g., a parabolic or a conical) profile towards a top center portion. The plasma source 106 comprises a ceramic (e.g., a dielectric) material. The plasma source 106 comprises an injector 107 located at the top center portion of the plasma source 106.

The showerhead 104 comprises a metallic material (e.g., aluminum or an alloy). The showerhead 104 is arranged between the plasma source 106 from the processing chamber 102. The showerhead 104 is arranged at the top of the processing chamber 102 and at the bottom of the plasma source 106. The showerhead 104 separates the plasma source 106 from the processing chamber 102. The processing chamber 102 is arranged on a first side (i.e., a substrate-facing side) of the showerhead 104. The plasma source 106 is arranged on a second side of the showerhead 104 that is opposite to the first side of the showerhead 104.

The processing chamber 102 comprises a pedestal 108. A substrate 110 is arranged on the pedestal 108 during processing. An actuator 112 is coupled to a stem portion of the pedestal 108. The actuator 112 can move the pedestal 108 vertically up and down relative to the showerhead 104 to adjust a gap between the substrate 110 and the showerhead 104.

The substrate processing system 100 comprises a gas delivery system 120 that supplies various gases to the processing chamber 102 and the plasma source 106. For example, during substrate processing, the gas delivery system 120 comprises a process gas supply 122, a purge gas supply 124, and a precursor supply 126. The process gas supply 122 can supply one or more process gases depending on the process being performed on the substrate 110. The purge gas supply 124 can supply one or more process gases (e.g., one or more inert gases). The precursor supply 126 can supply one or more precursors (reactants) depending on the process being performed on the substrate 110.

Further, while not shown, the gas delivery system 120 may also comprise a cleaning gas supply that can supply one or more cleaning gases to clean the processing chamber 102, the showerhead 104, and the plasma source 106 during preventive maintenance. Furthermore, while not shown, each of the process gas supply 122, the purge gas supply 124, and the precursor supply 126 (and the cleaning gas supply) comprises valves and mass flow controllers to control the supply of respective gases.

The gas delivery system 120 further comprises a plurality of valves (e.g., valves 130, 132, 134, and 136). The process gas supply 122 supplies the one or more process gas to the injector 107 via the valve 130. The purge gas supply 124 can supply the one or more purge gases to the injector 107 via the valve 132. The purge gas supply 124 can supply the one or more purge gases to the showerhead 104 via the valve 134. The precursor supply 126 can supply the one or more precursors to the showerhead 104 via the valve 136.

The showerhead 104 is a dual plenum showerhead. The showerhead 104 is generally cylindrical in shape. The showerhead 104 comprises an upper portion 103 and a lower portion 105. The upper portion 103 is cylindrical. The lower portion 105 is annular. The showerhead 104 is monolithic. That is, the upper portion 103 and the lower portion 105 are integral (i.e., a single piece). The upper portion 103 is also called a body of the showerhead 104. The body (i.e., upper portion) 103 of the showerhead 104 comprises upper, lower, and side surfaces that define the plenums in the showerhead 104 as described below in detail.

The plasma source 106 is mounted to the upper portion 103 of the showerhead 104. Specifically, the circular base portion of the plasma source 106 is mounted to the upper portion 103 of the showerhead 104. The lower portion 105 of the showerhead 104 extends vertically downwardly from a lower peripheral region of the upper portion 103 of the showerhead 104. The upper portion 103 of the showerhead 104 extends radially outwardly from an upper region of the lower portion 105 of the showerhead 104 forming a flange 101. Sidewalls of the processing chamber 102 are attached to a lower end of the lower portion 105 of the showerhead 104. The flange 101 of the showerhead 104 extends radially outwardly from the sidewalls of the processing chamber 102.

An outer diameter (OD) of the flange 101 of the showerhead 104 is an OD of the upper portion 103 of the showerhead 104. An OD of the lower portion 105 of the showerhead 104 is the same as an OD of the sidewalls of the processing chamber 102. The OD of the upper portion 103 of the showerhead 104 is greater than the OD of the lower portion 105 of the showerhead 104. An inner diameter (ID) of the lower portion 105 of the showerhead 104 is greater than an OD of the pedestal 108. Accordingly, the pedestal 108 can be moved vertically up and down by the actuator 112 to adjust the gap between the substrate 110 and the showerhead 104.

The showerhead 104 comprises two plenums in the upper portion 103 of the showerhead 104. The two plenums are defined by upper, lower, and side surfaces of the upper portion 103 of the showerhead 104. A first plenum 140 extends radially across the upper portion 103 of the showerhead 104. The first plenum 140 comprises an inlet 121 located on a periphery of the upper portion 103 (e.g., on the flange 101) of the showerhead 104. The first plenum 140 receives the one or more precursors through the inlet 121 from the precursor supply 126 via the valve 136. The first plenum 140 comprises a plurality of holes 142-1, 142-2, . . . , and 142-N (collectively the holes 142, N being a positive integer). The first plenum 140 supplies the one or more precursors via the holes 142 into the processing chamber 102. Accordingly, the holes 142 are also called the precursor holes 142. The inlet 121, the first plenum 140, and the precursor holes 142 are in fluid communication with each other.

The precursor holes 142 extend from the first plenum 140 to a bottom surface (i.e., a substrate-facing surface or a surface facing the processing chamber 102) of the upper portion 103 of the showerhead 104. For convenience, the first plenum 140 comprising the precursor holes 142 is collectively called the precursor plenum 140. The precursor holes 142 are distributed radially across the upper portion 103 of the showerhead 104 from the center of the showerhead 104 up to the ID of the lower portion 105 of the showerhead 104. The diameter of the first plenum 140 is greater than the diameter of the substrate 110.

The upper portion 103 of the showerhead 104 comprises a second plenum comprising a plurality of through holes 144-1, 144-2, . . . , and 144-N (collectively the through holes 144, N being a positive integer). The through holes 144 extend from the top surface of the upper portion 103 of the showerhead 104 to the bottom surface of the upper portion 103 of the showerhead 104. When plasma 113 is formed in the plasma source 106 as described below, ions from the plasma 113 are filtered by the through holes 144, and radicals from the plasma 113 pass via the through holes 144 into the processing chamber 102. Accordingly, the through holes 144 are also called the radical holes 144. The radical holes 144 are distributed radially across the upper portion 103 of the showerhead 104 from the center of the showerhead 104 up to the ID of the lower portion 105 of the showerhead 104.

The radical holes 144 are larger in diameter than the precursor holes 142. In some implementations, the diameter of the radical holes 144 may also be smaller and therefore equal to the diameter of the precursor holes 142. The radical holes 144 are not in fluid communication with the first plenum 140 and the precursor holes 142. For convenience, the radical holes 144 are collectively called the second plenum 144. The first plenum 140 and the second plenum 144 are disjoint from each other (i.e., are not in fluid communication with each other).

A coil (also called an antenna) 114 is arranged around the plasma source 106. An RF power supply 116 supplies RF power to the coil 114. When a process gas is injected into the plasma source 106 through the injector 107, the RF power supply 116 supplies RF power to the coil 114. The RF power supplied to the coil 114 activates the process gas to generate plasma 113 in the plasma source 106. The second plenum 144 (i.e., the radical holes 144) filters the ions from the plasma 113 and supplies the radicals from the plasma 113 into the processing chamber 102.

The showerhead 104 further comprises a cooling channel 146. The cooling channel 146 is disposed in the upper portion 103 of the showerhead 104. The cooling channel 146 is disposed above the first plenum 140 (i.e., the precursor plenum 140). The cooling channel 146 extends radially across the upper portion 103 of the showerhead 104. A fluid delivery system 150 circulates a coolant through the cooling channel 146 via an inlet and an outlet (both not shown) located on the periphery of the upper portion 103 (e.g., on the flange 101) of the showerhead 104. The cooling channel 146, the first plenum 140, and the second plenum 144 are disjoint from each other (i.e., are not in fluid communication with each other).

While not shown, the pedestal 108 also comprises cooling channels. The fluid delivery system 150 also circulates the coolant through the cooling channels in the pedestal 108 via an inlet and an outlet (both not shown) provided on the pedestal 108. The pedestal 108 further comprises a heater 109. The heater 109 heats the pedestal 108, which in turn heats the substrate 110. The pedestal 108 comprises a temperature sensor 152 to sense the temperature of the pedestal 108. The showerhead 104 also comprises a temperature sensor 154 to sense the temperature of the showerhead 104. A system controller 160 controls the heater 109 and the supply of the coolant from the fluid delivery system 150 to the pedestal 108 and the showerhead 104 to control the temperatures of the pedestal 108 and the showerhead 104.

The processing chamber 102 comprises a plurality of exhaust ports (not shown) arranged around a lower periphery of the sidewalls of the processing chamber 102. The exhaust ports are coupled to a foreline 162 that is coupled to the processing chamber 102 via a valve 166. The substrate processing system 100 comprises a vacuum pump 164 coupled to the processing chamber 102 and the foreline 162 through the valve 166. The vacuum pump 164 maintains pressure (e.g., vacuum) in the processing chamber 102 during substrate processing. The vacuum pump 164 also evacuates gases (e.g., precursors, process gases, purge gases, etc.) and reaction byproducts from the processing chamber 102 during substrate processing and cleaning processes performed during preventive maintenance. The system controller 160 controls all of the elements of the substrate processing system 100 described above.

An example of an ALD cycle comprising a dose step and a purge step that can be performed on the substrate 110 in the substrate processing system 100 is now described. For example, in the dose step, a precursor is supplied through the precursor plenum 142 into the processing chamber 102. A purge gas (e.g., an inert gas) is trickled (i.e., supplied at a low flow rate) through the injector 107 into the plasma source 106 to maintain a positive pressure in the plasma source 106.

A post-dose purge step follows the dose step. In the post-dose purge step, the plasma source 106 and the processing chamber 102 are purged with an inert gas. In the post-dose purge step, the trickle of the inert gas is maintained through the plasma source 106, and the purge gas is supplied through the precursor plenum 140 into the processing chamber 102. In some instances, the flow rate of the purge gas through the plasma source 106 may be increased to more than the trickle.

A conversion step follows the post-dose purge step. In the conversion step, a process gas (e.g., nitrogen) is supplied through the injector 107 into the plasma source 106 at a flow rate greater than the trickle. Nitrogen can also be supplied as the purge gas used in the purge steps of the ALD cycle. The RF power supply 116 supplies the RF power to the coil 114, which activates the process gas to strike plasma 113 in the plasma source 106. The second plenum 144 filters the ions from the plasma 113 and supplies the radicals from the plasma 113 into the processing chamber 102. The radicals react with the precursor that is deposited earlier on the substrate 110 during the dose step to deposit the desired material (e.g., silicon nitride) on the substrate 110.

A second purge step follows the conversion step. In the second purge step of the ALD cycle, at the end of the conversion step, the RF power supply 116 stops the supply of the RF power to the coil 114, which extinguishes the plasma 113 in the plasma source 106. The plasma source 106 and the processing chamber 102 are purged as described in the post-dose purge step above. The cycle of these steps is repeated until the material of desired thickness is deposited on the substrate 110. During the purge steps, the vacuum pump 164 evacuates the gases and the reaction byproducts the processing chamber 102.

In some processes, depending on the recipe used for processing the substrate 110, the same or a different precursor may be used in the dose steps in alternate ALD cycles. For example, a first precursor may be used during a first dose step in a first ALD cycle, and a second precursor may be used during a second dose step in a second ALD cycle that follows the first ALD cycle. These ALD cycles are repeated until the material of desired thickness is deposited on the substrate 110.

As described above, during substrate processing, some material may be deposited in regions 111 of the plasma source 106 between the windings of the coil 114. The material can build up over time and can act as a faraday cage to screen out electric fields from the coil 114 and can interfere with consistent power coupling to the plasma 113. A primary negative effect of the screening out of the electric fields from the coil 114 and the interference with consistent power coupling to the plasma 113 is process drift. Process drift can cause non-uniformities in substrate processing is therefore highly undesirable in semiconductor fabrication processes.

The present disclosure provides two schemes to minimize and clean the undesired deposition and buildup of material on the plasma source. In a first method, a secondary antenna is used in addition to a primary antenna. In a second method, a single antenna with spatial movement of the antenna is used. These methods are described below in detail for various shapes of the plasma source. Throughout the following description, the terms antenna(s) and coil(s) are used for elements 114, 115 interchangeably and synonymously.

### Section 2: Dual Antenna System—Dome Shaped Plasma Source

FIG. 2 shows a substrate processing system 200 comprising dual antennas (two coils) arranged around a dome shaped plasma source 106. The substrate processing system 200 is similar to the substrate processing system 100 shown in FIG. 1 in that the substrate processing system 200 also comprises the dome shaped plasma source used in the substrate processing system 100. The substrate processing system 200 differs from the substrate processing system 100 in that the substrate processing system 200 comprises a second coil 115 in addition to the coil 114 (also called the first coil) used in the substrate processing system 100. All elements identified in FIG. 2 with the same reference numerals used in FIG. 1 are not described again for brevity. Some elements shown in FIG. 1 are omitted in FIG. 2 for simplicity of illustration but are presumed present.

The coils 114 and 115 are also called antennas 114 and 115. Together, the coils 114 and 115 are called dual coils or dual antennas. The coil 114 can be called a first coil, a primary coil, a first antenna, or a primary antenna. The coil 115 can be called a second coil, a secondary coil, a second antenna, or a secondary antenna.

The first and second coils 114, 115 are disposed interstitially around the plasma source 106. Interstitially means interwoven, intertwined, interlaced, or wound around each other in an alternating manner. The first and second coils 114, 115 are co-wound and spatially interlaced with each other. For example, the windings of the first and second coils 114, 115 alternate with each other as shown. The first and second coils 114, 115 are not electrically connected to each other. Rather, the first and second coils 114, 115 are electrically isolated from each other. The windings of the second coil 115 cover the regions 111 of the plasma source 106 that lie between the windings of the first coil 114.

The substrate processing system 200 comprises a switching circuit 117. The switching circuit 117 is connected to RF power supply 116. The switching circuit 117 comprises a first output that is connected to the first coil 114. The switching circuit 117 comprises a second output that is connected to the second coil 115.

The system controller 160 is connected to the switching circuit 117. The system controller 160 controls the switching circuit 117. The system controller 160 and the switching circuit 117 control the amounts and durations of RF power supplied from the RF power supply 116 to the first and second coils 114, 115. The switching circuit 117 controls the supply of RF power from the RF power supply 116 to the first and second coils 114, 115. The switching circuit 117 supplies RF power from the RF power supply 116 alternatingly to the first and second coils 114, 115; and thus, the RF power supply 116 supplies RF power to the first and second coils 114, 115 in an alternating manner as follows.

The RF power supplied to the first coil 114 strikes plasma 113 in the processing chamber 102. In contrast, the RF power supplied to the second coil 115 cleans the material deposited or accumulated on the inner surface of the plasma source 106 in the regions 111 between the windings of the first coil 114. The RF power supplied to the second coil 115 does not generate plasma in the plasma source 106. Therefore, the switching circuit 117 supplies a small amount of RF power for a small time period to the second coil 115 compared to the first coil 114. For example, the RF power supplied to the second coil 115 may be less than 10% or 5% of the RF power supplied to the first coil 114. The switching circuit 117 supplies more RF power for a longer time period to the first coil (i.e., the primary antenna 114) than to the second coil (i.e., the secondary antenna) 115.

In general, the switching circuit 117 supplies a first amount of RF power from the RF power supply 116 via the first output to the first coil 114. The switching circuit 117 supplies a second amount of RF power from the RF power supply 116 via the second output to the second coil 115. The second amount is less than the first amount.

The switching circuit 117 supplies the first amount of RF power to the first coil 114 for a first time period. The switching circuit 117 supplies the second amount of RF power to the second coil 115 for a second time period. The second time period is less than the first time period.

The amounts of RF power supplied and the durations for which the RF power is supplied by the switching circuit 117 to the first and second coils 114, 115 may differ. The switching circuit 117 may use different combinations of the amounts of RF power supplied and the durations for which the amounts of RF power are supplied to the first and second coils 114, 115.

At any given time, the switching circuit 117 supplies majority (e.g., 90% or 95%) of the RF power from the RF power supply 116 to only one antenna (e.g., the first coil or primary antenna 114). By supplying RF power to the second coil (i.e., the secondary antenna) 115, the deposition and accumulation of material in the regions 111 of the plasma source 106 under the windings of the second coil (i.e., the secondary antenna) 115 can be minimized and/or cleaned. Consequently, process drift that can be otherwise caused by the material buildup in the regions 111 of the plasma source 106 is minimized or eliminated and non-uniformities in substrate processing are avoided.

### Section 3: Dual Antenna System—Cylindrical Plasma Source

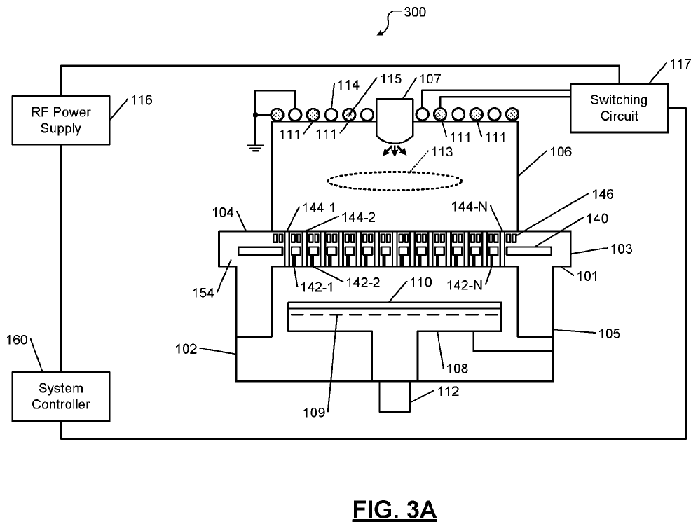

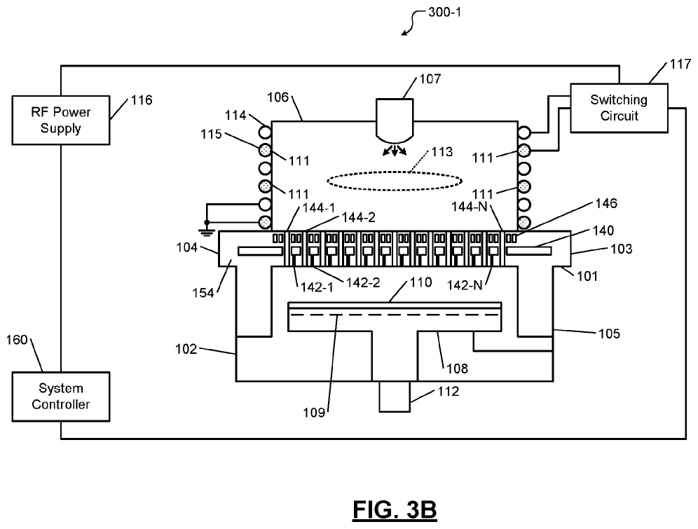

FIG. 3A shows a substrate processing system 300 comprising dual antennas (two coils) arranged on a cylindrical plasma source 106. The substrate processing system 300 is similar to the substrate processing system 200 shown in FIG. 2 except that the substrate processing system 300 comprises a cylindrical plasma source instead of a dome shaped plasma source. The first and second coils 114, 115 are arranged laterally on a top surface of the cylindrical plasma source 106. The first and second coils 114, 115 are arranged horizontally on the top surface of the cylindrical plasma source 106 in a plane parallel to a plane in which the upper portion 103 of the showerhead 104 lies. The top surface of the cylindrical plasma source 106 is opposite to a bottom surface of the cylindrical plasma source 106 that is attached to the upper portion 103 of the showerhead 104.

As in the substrate processing system 200 shown FIG. 2, the first and second coils 114, 115 are co-wound and spatially interlaced with each other. The first and second coils 114, 115 are disposed interstitially on the top surface of the cylindrical plasma source 106. For example, the windings of the first and second coils 114, 115 alternate with each other as shown. The windings of the second coil 115 cover the regions 111 on the top surface of the cylindrical plasma source 106 that lie between the windings of the first coil 114.

All elements identified in FIG. 3A with the same reference numerals used in FIGS. 1 and 2 are not described again for brevity. Some elements shown in FIG. 1 are omitted in FIG. 3A for simplicity of illustration but are presumed present. The switching circuit 117 controls the RF power supplied from the RF power supply 116 to the first and second coils 114, 115 as described above with reference to FIG. 2. The description is therefore not described again for brevity.

Again, at any given time, the majority of the RF power from the RF power supply 116 is applied to only one antenna (e.g., the first coil or primary antenna 114). By supplying RF power to the second coil (i.e., the secondary antenna) 115, the deposition and accumulation of material in the regions 111 on the top surface of the cylindrical plasma source 106 under the windings of the second coil (i.e., the secondary antenna) 115 can be minimized and/or cleaned. Consequently, process drift that can be otherwise caused by the material buildup in the regions 111 on the top surface of the cylindrical plasma source 106 is minimized or eliminated and non-uniformities in substrate processing are avoided.

FIG. 3B shows a substrate processing system 300-1 comprising dual antennas (two coils) arranged on the cylindrical plasma source 106. The substrate processing system 300-1 differs from the substrate processing system 300 shown in FIG. 3A in that the substrate processing system 300-1 comprises an alternate arrangement of the first and second coils 114, 115 on the cylindrical plasma source 106. Specifically, in the substrate processing system 300-1, the first and second coils 114, 115 are not arranged on the top surface of cylindrical plasma source 106. Instead, in the substrate processing system 300-1, the first and second coils 114, 115 are arranged around sidewalls of the cylindrical plasma source 106. The first and second coils 114, 115 are arranged vertically on the sidewalls of the cylindrical plasma source 106 along a vertical axis that is perpendicular to a plane in which the upper portion 103 of the showerhead 104 lies. Otherwise, the substrate processing system 300-1 is similar to the substrate processing system 300 shown in FIG. 3A.

As in the substrate processing systems 200 and 300 shown FIGS. 2 and 3A, the first and second coils 114, 115 are co-wound and spatially interlaced with each other. The first and second coils 114, 115 are disposed interstitially 111 around the sidewalls of the cylindrical plasma source 106. For example, the windings of the first and second coils 114, 115 alternate with each other as shown. The windings of the second coil 115 cover the regions 111 on the sidewalls of the cylindrical plasma source 106 that lie between the windings of the first coil 114.

All elements identified in FIG. 3B with the same reference numerals used in FIGS. 1, 2, and 3A are not described again for brevity. Some elements shown in FIG. 1 are omitted in FIG. 3B for simplicity of illustration but are presumed present. The switching circuit 117 controls the RF power supplied from the RF power supply 116 to the first and second coils 114, 115 as described above with reference to FIG. 2. The description is therefore not described again for brevity.

Again, at any given time, the majority of the RF power from the RF power supply 116 is applied to only one antenna (e.g., the first coil or primary antenna 114). By supplying RF power to the second coil (i.e., the secondary antenna) 115, the deposition and accumulation of material in the regions 111 on the sidewalls of the cylindrical plasma source 106 that lie under the windings of the second coil (i.e., the secondary antenna) 115 can be minimized and/or cleaned. Consequently, process drift that can be otherwise caused by the material buildup in the regions 111 on the top sidewalls of the plasma source 106 is minimized or eliminated and non-uniformities in substrate processing are avoided.

### Section 4: Dual Antenna System—Elliptical Plasma Source

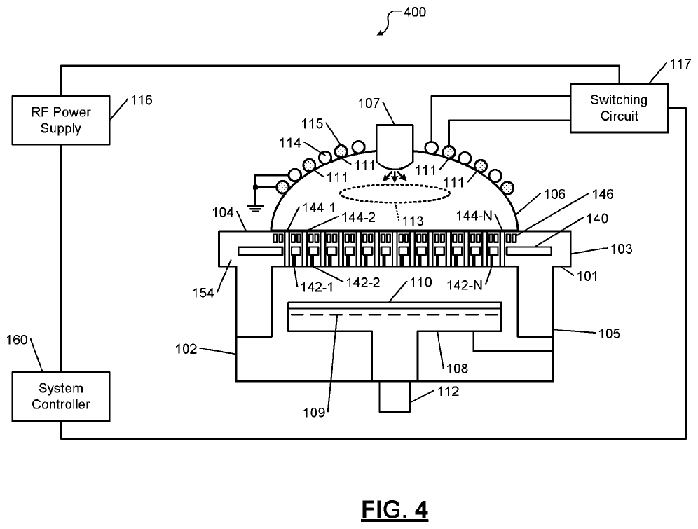

FIG. 4 shows a substrate processing system 400 comprising dual antennas (two coils) arranged around an elliptical plasma source 106. The substrate processing system 400 is similar to the substrate processing systems 200, 300, 300-1 shown in FIGS. 2, 3A, 3B except that the substrate processing system 400 comprises an elliptical plasma source instead of a dome shaped plasma source or a cylindrical plasma source. In the substrate processing system 400, the first and second coils 114, 115 are arranged around the elliptical plasma source 106.

As in the substrate processing systems 200, 300, 300-1 shown in FIGS. 2, 3A, 3B, the first and second coils 114, 115 are co-wound and spatially interlaced with each other. The first and second coils 114, 115 are disposed interstitially 111 around the elliptical plasma source 106. For example, the windings of the first and second coils 114, 115 alternate with each other as shown. The windings of the second coil 115 cover the regions 111 of the elliptical plasma source 106 that lie between the windings of the first coil 114.

All elements identified in FIG. 4 with the same reference numerals used in FIGS. 1, 2, 3A, and 3B are not described again for brevity. Some elements shown in FIG. 1 are omitted in FIG. 4 for simplicity of illustration but are presumed present. The switching circuit 117 controls the RF power supplied from the RF power supply 116 to the first and second coils 114, 115 as described above with reference to FIG. 2. The description is therefore not described again for brevity.

Again, at any given time, the majority of the RF power from the RF power supply 116 is applied to only one antenna (e.g., the first coil or primary antenna 114). By supplying RF power to the second coil (i.e., the secondary antenna) 115, the deposition and accumulation of material in the regions 111 of the elliptical plasma source 106 under the windings of the second coil (i.e., the secondary antenna) 115 can be minimized and/or cleaned. Consequently, process drift that can be otherwise caused by the material buildup in the regions 111 of the elliptical plasma source 106 is minimized or eliminated and non-uniformities in substrate processing are avoided.

### Section 5: Dual Antenna System—Conical Plasma Source

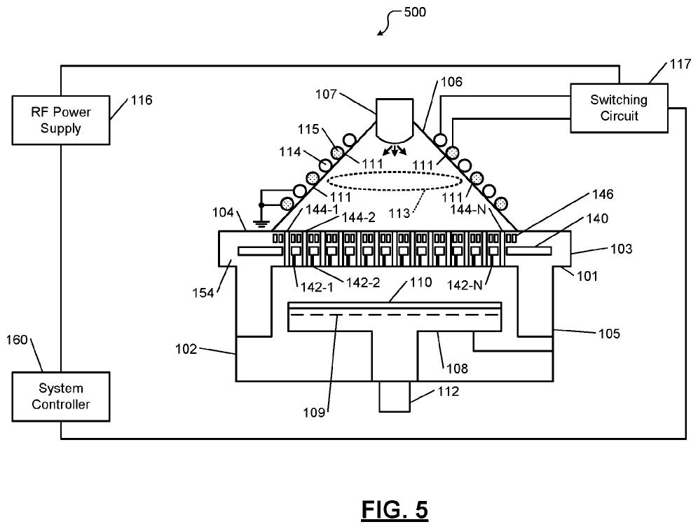

FIG. 5 shows a substrate processing system 500 comprising dual antennas (two coils) arranged around an elliptical plasma source 106. The substrate processing system 500 is similar to the substrate processing systems 200, 300, 300-1, 400 shown in FIGS. 2, 3A, 3B, 4 except that the substrate processing system 500 comprises a conical plasma source instead of a dome shaped plasma source, a cylindrical plasma source, or an elliptical plasma source. In the substrate processing system 500, the first and second coils 114, 115 are arranged around the conical plasma source 106.

As in the substrate processing system systems 200, 300, 300-1, 400 shown in FIGS. 2, 3A, 3B, 4, the first and second coils 114, 115 are co-wound and spatially interlaced with each other. The first and second coils 114, 115 are disposed interstitially 111 around the elliptical plasma source 106. For example, the windings of the first and second coils 114, 115 alternate with each other as shown. The windings of the second coil 115 cover the regions 111 of the conical plasma source 106 that lie between the windings of the first coil 114.

All elements identified in FIG. 5 with the same reference numerals used in FIGS. 1, 2, 3A, 3B, and 4 are not described again for brevity. Some elements shown in FIG. 1 are omitted in FIG. 5 for simplicity of illustration but are presumed present. The switching circuit 117 controls the RF power supplied from the RF power supply 116 to the first and second coils 114, 115 as described above with reference to FIG. 2. The description is therefore not described again for brevity.

Again, at any given time, the majority of the RF power from the RF power supply 116 is applied to only one antenna (e.g., the first coil or primary antenna 114). By supplying RF power to the second coil (i.e., the secondary antenna) 115, the deposition and accumulation of material in the regions 111 of the conical plasma source 106 under the windings of the second coil (i.e., the secondary antenna) 115 can be minimized and/or cleaned. Consequently, any process drift that can be otherwise caused by the material buildup in the regions 111 of the conical plasma source 106 is minimized or eliminated and non-uniformities in substrate processing are avoided.

### Section 6: Single Antenna System—Dome Shaped Plasma Source

FIG. 6 shows a substrate processing system 600 comprising a single antenna (a single coil) 114 arranged around a dome shaped plasma source 106. The substrate processing system 600 is similar to the substrate processing system 100 shown in FIG. 1 in that the substrate processing system 600 also comprises the dome shaped plasma source used in the substrate processing system 100. The substrate processing system 600 differs from the substrate processing system 100 in that the substrate processing system 600 comprises a coil movement system 119 to move the coil 114. The coil movement system 119 is described below in detail. All elements identified in FIG. 6 with the same reference numerals used in FIG. 1 are not described again for brevity. Some elements shown in FIG. 1 are omitted in FIG. 6 for simplicity of illustration but are presumed present.

The coil movement system 119 is connected to the coil 114. The system controller 160 is connected to the coil movement system 119. The system controller 160 controls the coil movement system 119. The coil movement system 119 moves or displaces the coil 114 between two positions on the surface or perimeter of the dome shaped plasma source 106. For example, the two positions may be called first and second positions. For example, the two positions may be called native and displaced positions. In FIGS. 6-9, the first position of the coil 114 is shown by showing the coil 114 using solid lines. The second (displaced) position of the coil 114 is shown by showing the coil 114 using dashed lines.

For example, the coil movement system 119 moves the coil 114 from the first position to the second position. Subsequently, the coil movement system 119 moves the coil 114 from the second position to the first position. The coil movement system 119 repeatedly moves (e.g., oscillates, dithers (i.e., moves intermittently or randomly), or vibrates) the coil 114 between the first position and the second position. For example, the coil movement system 119 may periodically vibrate the coil 114, may intermittently move the coil 114 to random positions between the first position and the second position. The coil movement system 119 may move the coil 114 between the first position and the second position periodically or continuously.

When the coil movement system 119 moves or displaces the coil 114 from the first position to the second position, the windings of the coil 114 move to the regions 111 of the dome shaped plasma source 106 that lie between the windings of the coil 114 when the coil 114 is in the first position. The coil movement system 119 moves the coil 114 while the RF power supply 116 supplies RF power to the coil 114. By moving the coil 114 between the first and second positions while supplying RF power to the coil 114, the deposition and accumulation of material in the regions 111 of the dome shaped plasma source 106 can be minimized and/or cleaned.

The coil movement system 119 can move or displace the coil 114 in many ways. The coil movement system 119 can comprise different types of actuators coupled to the coil 114 to move or displace the coil 114 in different ways. For example, the coil movement system 119 may comprise a stepper motor connected to an outermost winding of the coil 114. The stepper motor may repeatedly push and pull (e.g., compress and decompress) the coil 114.

In some examples, while not shown, the coil movement system 119 may comprise a first stepper motor connected to an uppermost winding of the coil 114 and a second stepper motor connected to a lowermost winding of the coil 114. The first and second stepper motors may move the coil 114 as follows.

For example, the first stepper motor connected to the uppermost winding may push the coil 114 downwards (towards the showerhead 104), and the second stepper motor connected to the lowermost winding may pull the coil 114 downwards (towards the showerhead 104). In some examples, the first stepper motor connected to the uppermost winding may push the coil 114 downwards (towards the showerhead 104), and the second stepper motor connected to the lowermost winding may push the coil 114 upwards (away from the showerhead 104).

The coil movement system 119 may repeat the push and pull actions of the first and second stepper motors. The coil movement system 119 may control the first and second stepper motors to implement different combinations of the push and pull actions. The coil movement system 119 may use any combinations of the above movements to move or displace the coil 114 between two or more positions. Further, the coil movement system 119 may repeat the movements in any sequence. In some examples, the movements can be randomized. Using these movements, the windings of the coil 114 are displaced and contact different regions (e.g., the regions 111) on the inner surface or perimeter of the dome shaped plasma source 106. The coil movement system 119 can move the coil 114 periodically or continuously.

In other examples, the coil movement system 119 may comprise a rotation system that rotates the coil 114 around the surface or perimeter of the dome shaped plasma source 106. For example, the rotation system of the coil movement system 119 rotates the coil 114 around a vertical axis that is perpendicular to a plane in which the upper portion 103 of the showerhead 104 lies. By rotating the coil 114, the windings of the coil 114 are displaced and contact different regions (e.g., the regions 111) on the inner surface or perimeter of the dome shaped plasma source 106.

For example, the rotating system of the coil movement system 119 can rotate the coil 114 around the vertical axis in a clockwise direction to a first position. Subsequently, the rotating system of the coil movement system 119 can rotate the coil 114 around the vertical axis in a counterclockwise direction to a second position. The rotating system of the coil movement system 119 can repeatedly move the coil 114 between the first and second positions. The rotating system of the coil movement system 119 may move the coil 114 between the first and second positions periodically or continuously.

In some examples, the rotating system of the coil movement system 119 may rotate the coil 114 by rotating the entire electrical system (e.g., by rotating the RF power supply 116 and the coil 114). In other examples, the rotating system of the coil movement system 119 may rotate the coil 114 using an electrical rotation coupling device such as an electrical slip ring. Other examples of slip rings include liquid mercury slip rings, ball bearing based slip rings, and so on. The linear and rotating mechanisms of the coil movement system 119 that move the coil 114 linearly and that rotate the coil 114 as described above can be collectively called actuators of the coil movement system 119 that move the coil 114.

In the examples described above, the coil movement system 119 moves the coil 114 while the RF power supply 116 supplies RF power to the coil 114. By moving the coil 114 while supplying RF power to the coil 114, the deposition and accumulation of material in the regions 111 of the dome shaped plasma source 106 that lie between the windings of the coil 114 can be minimized and/or cleaned. Consequently, process drift that can be otherwise caused by the material buildup in the regions 111 of the dome shaped plasma source 106 is minimized or eliminated and non-uniformities in substrate processing are avoided.

### Section 7: Single Antenna System—Cylindrical Plasma Source

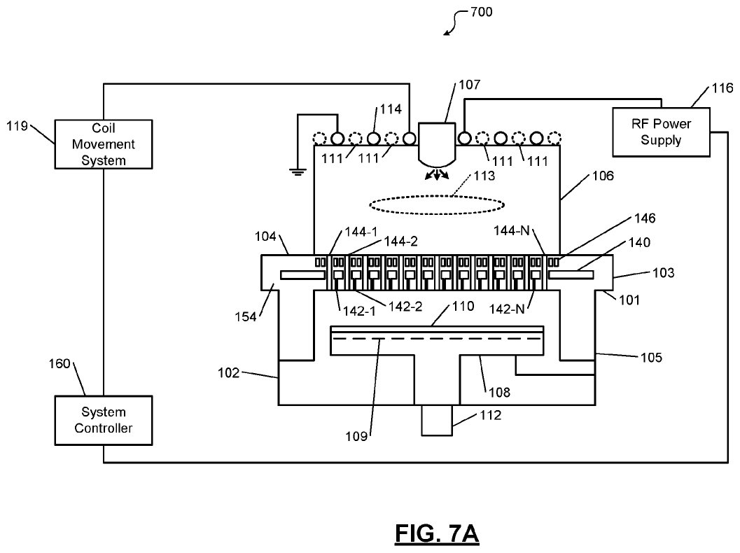

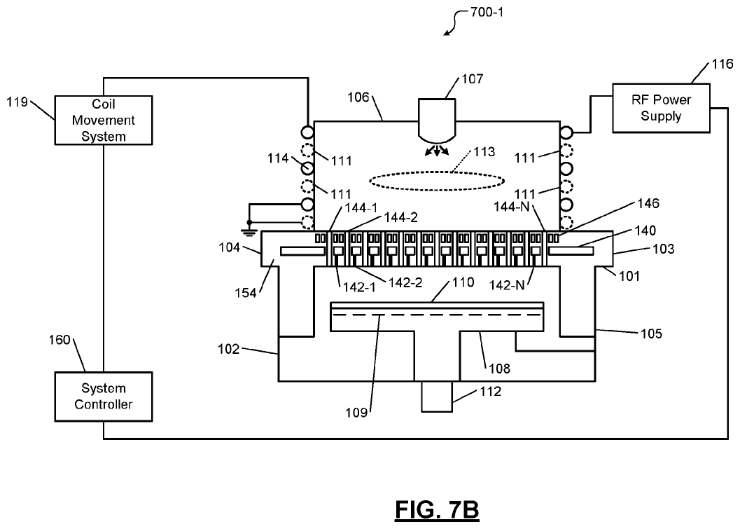

FIG. 7A shows a substrate processing system 700 comprising a single antenna (a single coil) 114 arranged on a cylindrical plasma source 106. The substrate processing system 700 is similar to the substrate processing system 600 shown in FIG. 6 except that the substrate processing system 700 comprises a cylindrical plasma source instead of a dome shaped plasma source. All elements identified in FIG. 7A with the same reference numerals used in FIGS. 1 and 6 are not described again for brevity. Some of the elements shown in FIG. 1 are omitted in FIG. 7A for simplicity of illustration but are presumed present.

The coil 114 is arranged laterally on a top surface of the cylindrical plasma source 106. The coil 114 is arranged horizontally on the top surface of the cylindrical plasma source 106 in a plane parallel to a plane in which the upper portion 103 of the showerhead 104 lies. The top surface of the cylindrical plasma source 106 is opposite to a bottom surface of the cylindrical plasma source 106 that is attached to the upper portion 103 of the showerhead 104.

The coil movement system 119 can move or displace the coil 114 laterally along the plane that is parallel to the plane in which the upper portion 103 of the showerhead 104 lies. For example, one or two stepper motors can move (displace) the coil 114 linearly along the plane that is parallel to a plane in which the upper portion 103 of the showerhead 104 lies. Alternatively, the coil movement system 119 can rotate the coil 114 around a vertical axis that is perpendicular to the plane in which the upper portion 103 of the showerhead 104 lies. The coil movement system 119 can move the coil 114 linearly or by rotating the coil 114 in different ways as described above with reference to FIG. 6. The description is therefore not repeated for brevity. By moving the coil 114 laterally or by rotating the coil 114, the windings of the coil 114 are displaced and contact different regions (e.g., the regions 111) on the top inner surface of the cylindrical plasma source 106.

The coil movement system 119 moves the coil 114 (laterally or by rotating the coil 114) while the RF power supply 116 supplies RF power to the coil 114. By moving the coil 114 while supplying RF power to the coil 114, the deposition and accumulation of material in the regions 111 on the top surface of the cylindrical plasma source 106 can be minimized and/or cleaned. Consequently, any process drift that can be otherwise caused by the material buildup in the regions 111 on the top surface of the cylindrical plasma source 106 is minimized or eliminated and non-uniformities in substrate processing are avoided.

FIG. 7B shows a substrate processing system 700-1 comprising a single antenna (a single coil) 114 arranged on a cylindrical plasma source 106. The substrate processing system 700-1 differs from the substrate processing system 700 shown in FIG. 7A in that the substrate processing system 700-1 comprises an alternate arrangement of the first coil 114 on the cylindrical plasma source 106. Specifically, in the substrate processing system 700-1, the first coil 114 is not arranged on the top surface of cylindrical plasma source 106. Instead, in the substrate processing system 700-1, the coil 114 is arranged around sidewalls of the cylindrical plasma source 106. The coil 114 is arranged vertically on the sidewalls of the cylindrical plasma source 106 along an axis that is perpendicular to a plane in which the upper portion 103 of the showerhead 104 lies. Otherwise, the substrate processing system 700-1 is similar to the substrate processing system 700 shown in FIG. 7A. All elements identified in FIG. 7B with the same reference numerals used in FIGS. 1, 6, and 7A are not described again for brevity. Some elements shown in FIG. 1 are omitted in FIG. 7B for simplicity of illustration but are presumed present.

The coil movement system 119 can move or displace the coil 114 linearly along the vertical axis that is perpendicular to the plane in which the upper portion 103 of the showerhead 104 lies. For example, one or two stepper motors can move (displace) the coil 114 linearly along the vertical axis that is perpendicular to the plane in which the upper portion 103 of the showerhead 104 lies. Alternatively, the coil movement system 119 can rotate the coil 114 around the vertical axis that is perpendicular to the plane in which the upper portion 103 of the showerhead 104 lies. The coil movement system 119 can move the coil 114 linearly and by rotating the coil 114 in different ways as described above with reference to FIG. 6. The description is therefore not repeated for brevity. By moving the coil 114 laterally or by rotating the coil 114, the windings of the coil 114 are displaced and contact different regions (e.g., the regions 111) on the sidewalls of the cylindrical plasma source 106.

The coil movement system 119 moves the coil 114 (laterally or by rotating the coil 114) while the RF power supply 116 supplies RF power to the coil 114. By moving the coil 114 while supplying RF power to the coil 114, the deposition and accumulation of material in the regions 111 on the sidewalls of the cylindrical plasma source 106 can be minimized and/or cleaned. Consequently, any process drift that can be otherwise caused by the material buildup in the regions 111 on the top surface of the cylindrical plasma source 106 is minimized or eliminated and non-uniformities in substrate processing are avoided.

### Section 8: Single Antenna System—Elliptical Plasma Source

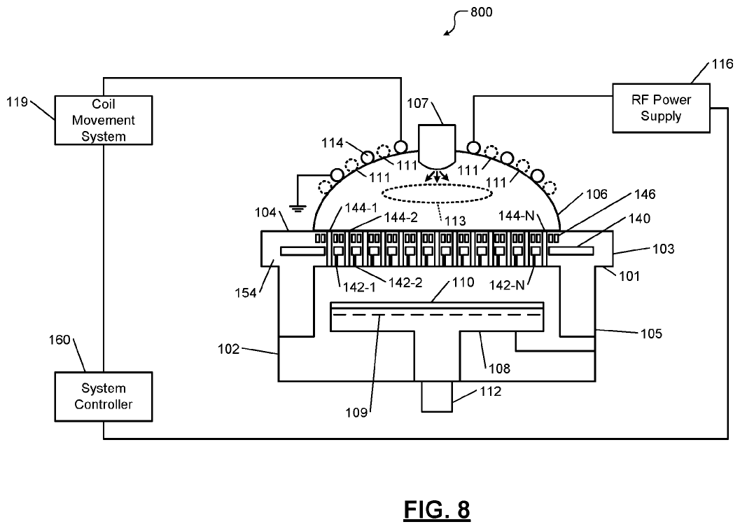

FIG. 8 shows a substrate processing system 800 comprising a single antenna (a single coil) 114 arranged around an elliptical plasma source 106. The substrate processing system 800 is similar to the substrate processing systems 600, 700, 700-1 shown in FIGS. 6, 7A, 7B except that the substrate processing system 800 comprises an elliptical plasma source instead of a dome shaped plasma source or a cylindrical plasma source. In the substrate processing system 800, the coil 114 is arranged around the elliptical plasma source 106. All elements identified in FIG. 8 with the same reference numerals used in FIGS. 1, 6, 7A, and 7B are not described again for brevity. Some elements shown in FIG. 1 are omitted in FIG. 8 for simplicity of illustration but are presumed present.

The coil movement system 119 can move or displace the coil 114 along the surface or perimeter of the elliptical plasma source 106 in different ways as described above with reference to FIG. 6. Alternatively, the coil movement system 119 can rotate the coil 114 in different ways as described above with reference to FIG. 6. The description is therefore not repeated for brevity. By moving or rotating the coil 114, the windings of the coil 114 are displaced and contact different regions (e.g., the regions 111) on the surface the elliptical plasma source 106.

The coil movement system 119 moves or rotates the coil 114 while the RF power supply 116 supplies RF power to the coil 114. By moving or rotating the coil 114 while supplying RF power to the coil 114, the deposition and accumulation of material in the regions 111 of the elliptical plasma source 106 can be minimized and/or cleaned. Consequently, any process drift that can be otherwise caused by the material buildup in the regions 111 of the elliptical plasma source 106 is minimized or eliminated and non-uniformities in substrate processing are avoided.

### Section 9: Single Antenna System—Conical Plasma Source

FIG. 9 shows a substrate processing system 900 comprising a single antenna (a single coil) 114 arranged around a conical plasma source 106. The substrate processing system 900 is similar to the substrate processing systems 600, 700, 700-1, 800 shown in FIGS. 6, 7A, 7B, 8 except that the substrate processing system 500 comprises a conical plasma source instead of a dome shaped plasma source, a cylindrical plasma source, or an elliptical plasma source. In the substrate processing system 900, the coil 114 is arranged around the conical plasma source 106. All elements identified in FIG. 9 with the same reference numerals used in FIGS. 1, 6, 7A, 7B, and 8 are not described again for brevity. Some elements shown in FIG. 1 are omitted in FIG. 9 for simplicity of illustration but are presumed present.

The coil movement system 119 can move or displace the coil 114 along the surface or perimeter of the conical plasma source 106 in different ways as described above with reference to FIG. 6. Alternatively, the coil movement system 119 can rotate the coil 114 in many different as described above with reference to FIG. 6. The description is therefore not repeated for brevity. By moving or rotating the coil 114, the windings of the coil 114 are displaced and contact different regions (e.g., the regions 111) on the inner surface of the conical plasma source 106.

The coil movement system 119 moves or rotates the coil 114 while the RF power supply 116 supplies RF power to the coil 114. By moving or rotating the coil 114 while supplying RF power to the coil 114, the deposition and accumulation of material in the regions 111 of the conical plasma source 106 can be minimized and/or cleaned. Consequently, any process drift that can be otherwise caused by the material buildup in the regions 111 of the conical plasma source 106 is minimized or eliminated and non-uniformities in substrate processing are avoided.

### Section 10: Control Method—Dual Antenna System

FIG. 10 shows a method 1000 for controlling the dual antennas (coils 114, 115) shown and described above with reference to FIGS. 2-5. For example, the system controller 160 and the switching circuit 117 shown and described above with reference to FIGS. 2-5 can perform the method 1000.

At 1002, two coils 114, 115 are spatially interlaced with each other around the plasma source 106 as described above with reference to FIGS. 2-5. At 1004, the substrate 110 is loaded into the processing chamber 102. At 1006, to process the substrate 110 in the processing chamber 102, the gas delivery system 120 supplies process gases into the plasma source 106 as described above with reference to FIG. 1.

At 1008, the system controller 160 and the switching circuit 117 control RF power supplied to the two coils 114, 115 as described above with reference to FIGS. 2-5. The RF power supplied to the coil 114 ignites the gases in the plasma source 106 and strikes plasma 113 in the plasma source 106 to deposit material on the substrate 110. The RF power supplied to the coil 115 minimizes and/or cleans any deposition of material in the regions 111 of the plasma source 106. At 1010, material is deposited on the substrate 110 using the plasma 113.

### Section 11: Control Method—Single Antenna System

FIG. 11 shows a method 1100 for controlling the single antenna (coil 114) shown and described above with reference to FIGS. 6-9. For example, the system controller 160 and the coil movement system 119 shown and described above with reference to FIGS. 6-9 can perform the method 1100.

At 1102, the coil 114 is arranged around the plasma source 106 as described above with reference to FIGS. 6-9. At 1104, the substrate 110 is loaded into the processing chamber 102. At 1106, to process the substrate 110 in the processing chamber 102, the gas delivery system 120 supplies process gases into the plasma source 106 as described above with reference to FIG. 1.

At 1108, the RF power supply 116 supplies RF power to the coil 114 as described above with reference to FIGS. 6-9. The RF power supplied to the coil 114 ignites the gases in the plasma source 106 and strikes plasma 113 in the plasma source 106 to deposit material on the substrate 110. At 1110, the system controller 160 and the coil movement system 119 intermittently or continuously move the coil 114 around the plasma source 106 as described above with reference to FIGS. 6-9. The movement of the coil 114 minimizes and/or cleans any deposition of material in the regions 111 of the plasma source 106 while material is deposited on the substrate 110 using the plasma 113.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the examples is described above as having certain features, any one or more of those features described with respect to any one of the examples of the disclosure can be implemented in and/or combined with features of any of the other examples, even if that combination is not explicitly described. In other words, the described examples are not mutually exclusive, and permutations of one or more examples with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate.

The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some examples, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing system comprising:
a processing chamber;
a plasma source configured to supply a plasma to the processing chamber through a gas distribution device disposed between the processing chamber and the plasma source;
a first coil and a second coil disposed interstitially on the plasma source and configured to ignite a gas supplied to the plasma source to generate the plasma; and
a power supply configured to supply power to the first coil and the second coil in an alternating manner.

2. The substrate processing system of claim 1 wherein the power supply is configured to supply more power to the first coil than to the second coil.

3. The substrate processing system of claim 1 wherein windings of the first coil and the second coil are interlaced with each other.

4. The substrate processing system of claim 1 wherein the first coil and the second coil are electrically isolated from each other.

5. The substrate processing system of claim 1 further comprising a switching circuit connected to the power supply, the switching circuit comprising a first output connected to the first coil and a second output connected to the second coil, the switching circuit configured to supply the power from the power supply to the first and second coils via the first and second outputs, respectively, in the alternating manner.

6. The substrate processing system of claim 1 wherein the power supply is configured to supply a first radio frequency power to the first coil and supply a second radio frequency power to the second coil.

7. The substrate processing system of claim 6 wherein the first radio frequency power supplied to the first coil is greater than the second radio frequency power supplied to the second coil.

8. The substrate processing system of claim 6 wherein the power supply is configured to supply the first radio frequency power to the first coil for a first time period and supply the second radio frequency power to the second coil for a second time period.

9. The substrate processing system of claim 8 wherein the first time period is greater than the second time period.

10. The substrate processing system of claim 8 wherein the first radio frequency power supplied to the first coil for the first time period is greater than the second radio frequency power supplied to the second coil for the second time period and wherein the first time period is greater than the second time period.

11. The substrate processing system of claim 1 wherein the power supply is configured to supply the power to the first coil to generate the plasma.

12. The substrate processing system of claim 1 wherein the power supply is configured to supply the power to the second coil to erode material deposited on an inner surface of the plasma source in regions between windings of the first coil.

13. The substrate processing system of claim 1 wherein the plasma source is dome shaped, cylindrical, elliptical, or conical.

14. The substrate processing system of claim 1 wherein the plasma source is dome shaped, cylindrical, elliptical, or conical; and wherein the first and second coils are disposed around the plasma source.

15. The substrate processing system of claim 1 wherein the plasma source is cylindrical with a first end coupled to the gas distribution device, and wherein the first and second coils are disposed on a surface at a second end of the plasma source.

16. The substrate processing system of claim 1 further comprising:
an injector coupled to the plasma source, the injector configured to inject a gas into the plasma source to generate the plasma; and
a pedestal arranged in the processing chamber to support a substrate,
wherein the gas distribution device is configured to filter ions from the plasma and supply radicals from the plasma into the processing chamber to process the substrate.

17. A substrate processing system comprising:
a processing chamber;
a plasma source configured to supply a plasma to the processing chamber through a gas distribution device disposed between the processing chamber and the plasma source;
a coil disposed on the plasma source and configured to ignite a gas supplied to the plasma source to generate the plasma; and
an actuator configured to shift a position of the coil on the plasma source.

18. The substrate processing system of claim 17 further comprising a power supply configured to supply power to the coil to ignite the gas wherein the actuator is configured to shift the position of the coil while the power supply supplies power to the coil.

19. The substrate processing system of claim 18 wherein the actuator is configured to shift the position of the coil to erode material deposited on an inner surface of the plasma source in regions between windings of the coil.

20. The substrate processing system of claim 17 wherein the actuator is configured to shift the position of the coil intermittently.

21. The substrate processing system of claim 17 wherein the actuator is configured to shift the position of the coil periodically.

22. The substrate processing system of claim 17 wherein the actuator is configured to shift the position of the coil repeatedly between two positions.

23. The substrate processing system of claim 17 wherein the actuator is configured to shift the position of the coil linearly between two positions.

24. The substrate processing system of claim 17 wherein the actuator is configured to shift the position of the coil by rotating the coil to move windings of the coil over different regions of the plasma source.

25. The substrate processing system of claim 17 wherein the actuator is configured to shift the position of the coil by compressing and decompressing the coil.

26. The substrate processing system of claim 17 wherein the actuator is configured to shift the position of the coil by vibrating the coil periodically.

27. The substrate processing system of claim 17 wherein the plasma source is dome shaped, cylindrical, elliptical, or conical.

28. The substrate processing system of claim 17 wherein the plasma source is dome shaped, cylindrical, elliptical, or conical; and wherein the coil is disposed around the plasma source.

29. The substrate processing system of claim 17 wherein the plasma source is cylindrical with a first end coupled to the gas distribution device, and wherein the coil disposed on a surface at a second end of the plasma source.

30. The substrate processing system of claim 17 further comprising:
an injector coupled to the plasma source, the injector configured to inject a gas into the plasma source to generate the plasma; and
a pedestal arranged in the processing chamber to support a substrate,
wherein the gas distribution device is configured to filter ions from the plasma and supply radicals from the plasma into the processing chamber to process the substrate.
